(19) United States
(12) Patent Application Publication
(10) Pub. No.: US 2022/0102688 A1
(43) Pub. Date: Mar. 31, 2022

(54) ORGANIC LIGHT EMITTING TRANSISTOR DEVICES WITH SHARED SUBSTRATES

(71) Applicant: Hewlett-Packard Development Company, L.P., Spring, TX (US)

(72) Inventors: Hsing-Hung Hsieh, Taipei City (TW); Alan Man Pan Tam, Spring, TX (US); Super Liao, Taipei City (TW)

(73) Assignee: Hewlett-Packard Development Company, L.P., Spring, TX (US)

(21) Appl. No.: 17/297,232

(22) PCT Filed: Jun. 14, 2019
(86) PCT No.: PCT/US2019/037188

§ 371 Date: May 26, 2021

(51) Int. Cl. H01L 51/52; H01L 27/28; H01L 51/56

(52) U.S. Cl. CPC H01L 51/5296; H01L 51/56; H01L 27/283

(57) ABSTRACT

In example implementations, an organic light emitting transistor is provided. The organic light emitting transistor includes a substrate, at least one layer deposited onto the substrate, a thin film transistor, and an organic light emitting transistor. The thin film transistor is formed on the substrate to include a first portion of the at least one layer and the organic light emitting transistor is formed on the substrate to include a second portion of the at least one layer.

### BACKGROUND

Displays can be used to produce visible images. Displays have evolved over time from cathode ray tube (CRT) based displays to light emitting diode (LED) based displays. The LED based displays can provide a smaller and lighter display that is more energy efficient than CRT based displays.

### BRIEF DESCRIPTION OF THE DRAWINGS

FIG. 1 is a block diagram of an example apparatus with an organic light emitting field effect transistor (OLET) of the present disclosure;

FIG. 2 is a block diagram of an example OLET device with a shared substrate of the present disclosure;

FIG. 3 is a cross-sectional block diagram of an example OLET device with a shared substrate of the present disclosure;

FIGS. 4A-H are block diagrams of a process flow for fabricating the OLET device with the shared substrate of the present disclosure; and

FIG. 5 is a flow chart of an example method for fabricating the OLET device with the shared substrate of the present disclosure the present disclosure.

### DETAILED DESCRIPTION

Examples described herein provide an organic light emitting field effect transistor (OLET) device with a shared substrate. As discussed above, some displays are being fabricated with light emitting diodes (LED). As LED technology has improved, organic LEDs are being developed that can be smaller and more energy efficient than traditional LEDs and can be used as lighting in displays.

A further development in the LED technology has led to OLETs. OLETs provide high contrast ratio, fast response time, vivid color, light weight, and a thin form factor. The OLET combines thin film transistor (TFT) functions and light emission properties. The OLET turns the emission device from a current driven device to a voltage driven device. As a result, the OLET does not use a high quality driving TFT and provides lower barriers for production.

However, an OLET display uses both the TFT and the OLET. Some processes to manufacture the OLET display may manufacture the TFT and the OLET separately and build each layer of the TFT and the OLET separately. As a result, the overall design of the OLET display and the process to manufacture the OLET display can be inefficient.

Examples herein provide an OLET display design and process to manufacture the same that reduces the overall number layers for the OLET display. The reduction in the number of layers results in a reduction in manufacturing time of the OLET display. For example, the OLET may share a substrate and may also share additional layers with the TFT to reduce the amount of processing to build the OLET display. The reduction in the number of layers and in the manufacturing time of the OLET display may provide a more efficient process that is cheaper and faster than other processes.

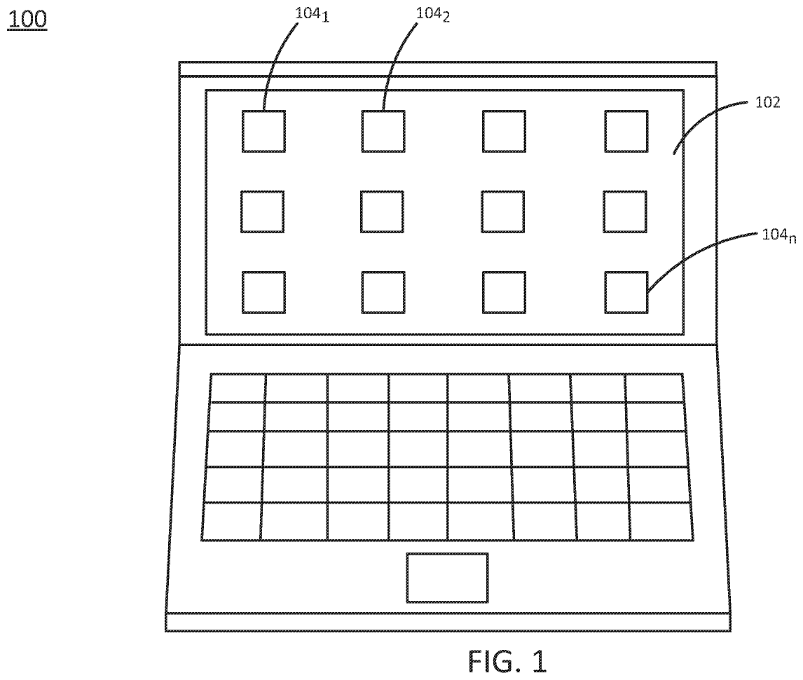

FIG. 1 illustrates an example of an apparatus 100 that includes the OLET devices of the present disclosure. In one example, the apparatus 100 may be a laptop computer or a monitor that includes a display 102. The display 102 may include a plurality of OLET devices 104₁ to 104ₙ (hereinafter also referred to individually as an OLET device 104 or collectively as OLET devices 104). The OLET devices 104 may provide backlighting for the display 102. As discussed above, OLET devices 104 may combine the functions of TFTs and OLETs and may be integrated into substrates like silicon or glass.

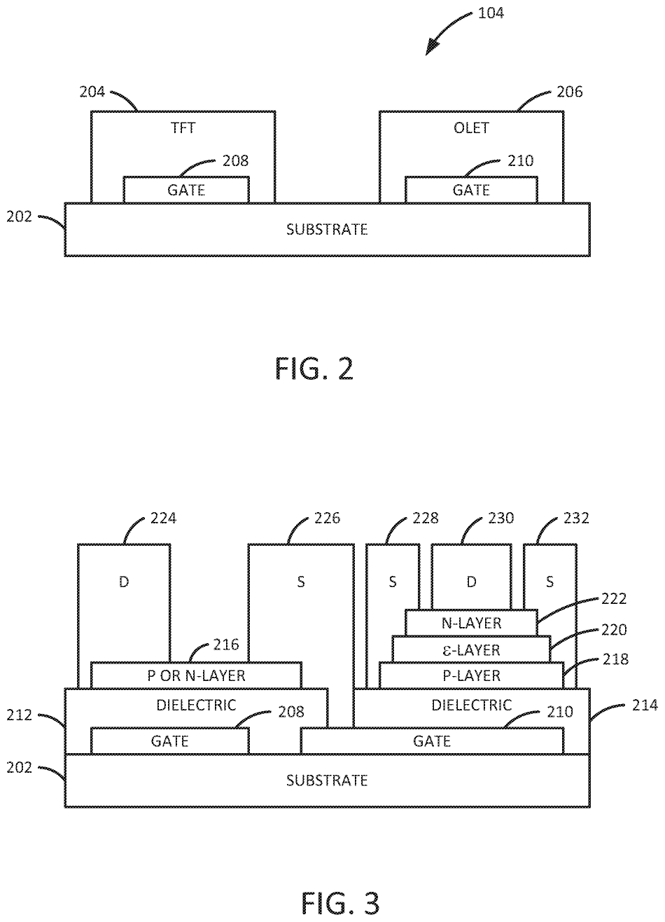

FIG. 2 illustrates a block diagram of the OLET device 104 of the present disclosure. In one example, the OLET device 104 includes a substrate 202, a TFT 204 and an OLET 206. The TFT 204 and the OLET 206 may both be formed on the substrate 202. In other words, the TFT 204 and the OLET 206 share the substrate 202. The substrate 202 may be glass or plastic.

Portions of the TFT 204 and the OLET 206 may be manufactured at the same time or in parallel rather than being built as separate layers that are stacked on top of one another. For example, at least one layer of the TFT 204 and the OLET 206 may be formed from a single layer that is deposited onto the substrate 202. For example, the TFT 204 may be formed on the substrate 202 to include a first portion of the single layer that is deposited onto the substrate 202 and the OLET 206 may be formed on the substrate 202 to include a second portion of the single layer that is deposited onto the substrate 202.

FIG. 2 illustrates a gate 208 of the TFT 204 and a gate 210 of the OLET 206. The gate 208 and the gate 210 can be formed from a single gate layer deposited onto the substrate 202. Other layers (e.g., the dielectric layer, the p-layer, or the n-layer) of the TFT 204 and the OLET 206 may also be formed from a common layer that is deposited, as discussed in further details below.

As noted above, the OLET device 104 of the present disclosure reduces the overall number of layers that are formed to build the OLET device 104 by forming some layers of the TFT 204 and the OLET 206 from a common layer. Said another way, a single layer may be deposited, and portions of both the TFT 204 and the OLET 206 may be formed from the single layer that is deposited.

Previous manufacturing methods may build the OLET device by forming each layer of the TFT and the OLET separately. Thus, the OLET is stacked on top of the TFT. Up to eleven different layers may be formed to build the OLET. In contrast, the OLET device 104 may be formed by forming some layers of the TFT 204 and the OLET 206 from a single deposited layer. This may reduce the number of layers to be formed to as low as six layers to build the OLET device 104.

In addition, the TFT 204 and the OLET 206 may share the same substrate 202. This may be in contrast to stacking the OLET on top of the TFT as done in previous OLET device designs. By sharing the same substrate, some layers may be eliminated. For example, when the OLET is stacked on top of the TFT, a passivation layer may be formed to insulate the gate of the TFT and the gate of the OLET from one another. The OLET device 104 of the present disclosure eliminates the use of the passivation layer by allowing the OLET 206 and the TFT 204 to share the substrate 202, rather than stacking the OLET 206 on top of the TFT 204. Thus, the overall number of layers that are formed to build the OLET device 104 may be reduced and the size of the stack of the OLET device 104 may also be reduced.

FIG. 3 illustrates a cross-sectional block diagram of the OLET device 104. In one example, the OLET device 104 may include the substrate 202. The substrate 202 may be glass or plastic.

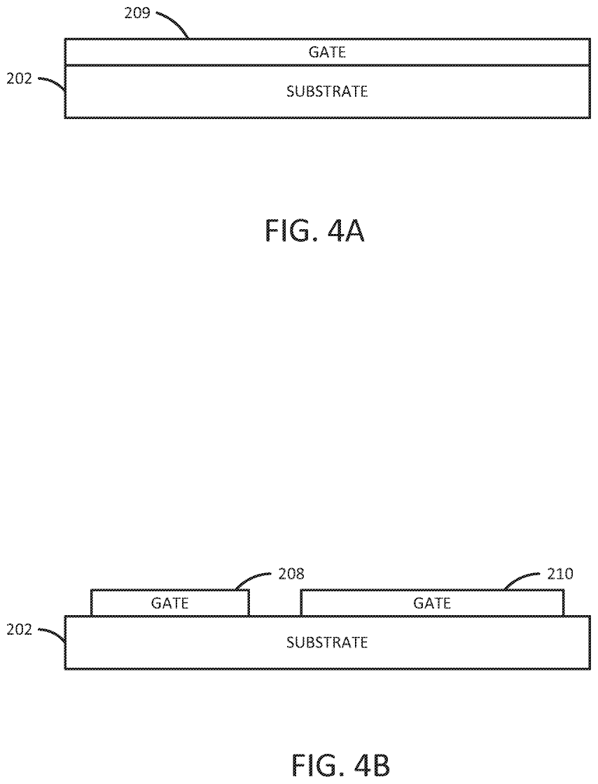

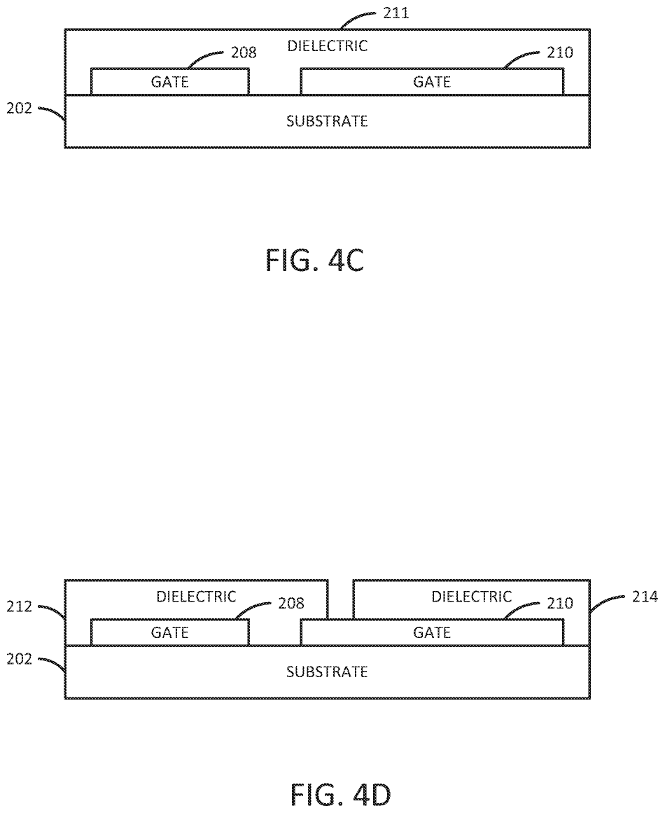

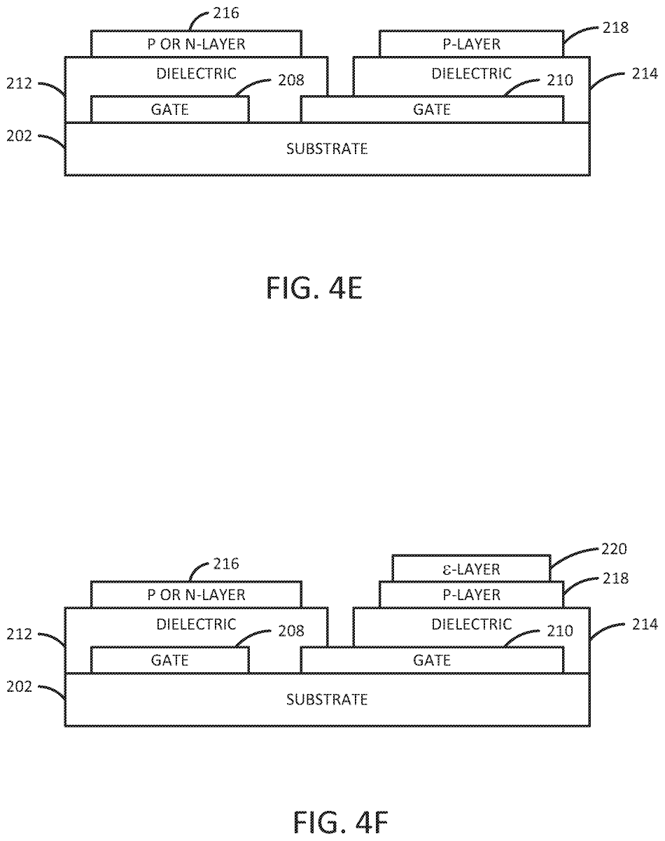

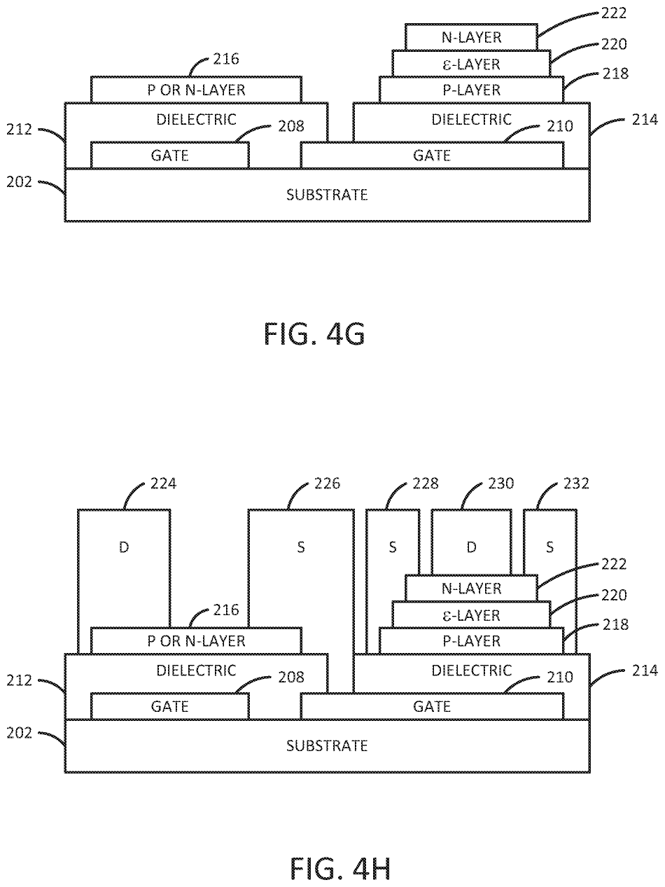

A first gate 208 and a second gate 210 may be formed on the substrate 202. In one example, the first gate 208 and the second gate 210 may be formed from a metal, a metallic compound, or a ceramic (e.g., including ceramic powders and build materials). Examples of metals or metallic compounds may include molybdenum (Mo), aluminum (Al), copper (Cu), Titanium (Ti), silver (Ag), or gold (Au). Examples of ceramics may include transition metal oxides such as indium tin oxide (ITO) or indium zinc oxide (IZO). The first gate 208 and the second gate 210 may be formed to have a thickness of approximately 50-500 nanometers (nm). In one example, the thickness may be approximately 100 nm-300 nanometers. The first gate 208 and the second gate 210 may be formed from a single gate layer that is deposited onto the substrate 202, as discussed in detail below with reference to FIGS. 4A-4H.

A first dielectric layer 212 may be formed over the first gate 208 and a second dielectric layer 214 may be formed over the second gate 210. In one example, the first dielectric layer 212 and the second dielectric layer 214 may be formed from materials such as silicon dioxide, silicon nitride, aluminum oxide, hafnium oxide, or an insulative polymer. The first dielectric layer 212 and the second dielectric layer 214 may be formed to have a thickness of approximately 100-1000 nm. In one example, the thickness may be approximately 200-500 nm. The first dielectric layer 212 and the second dielectric layer 214 may be formed from a single dielectric layer that is deposited over the first gate 208 and the second gate 210, as discussed in detail below with reference to FIGS. 4A-4H.

A layer 216 may be deposited over the first dielectric layer 212. The layer 216 may be the first p-layer or the first n-layer depending on whether the TFT 204 is manufactured to be a p-type TFT or an n-type TFT. For example, if the layer 216 is a p-layer, the layer 216 may be formed on the first dielectric layer 212 at the same time a second p-layer 218 is formed on the second dielectric layer 214. If the layer 216 is an n-layer, then the layer 216 may be formed at the same time a second n-layer 222 is formed.

The p-layer 218 may be formed on the second dielectric layer 214. If the layer 216 is a p-layer, the layer 216 for a p-type TFT and the p-layer 218 may formed from a semiconductor material (e.g., Poly(3-hexylthiophene (P3HT), triphenylamine and derivatives thereof) and doped with p-type dopants. The p-layer 218 and the layer 216 fora p-type TFT may be formed to be have a thickness of approximately 10-50 nm. In one example, the thickness may be approximately 30-50 nm.

An emissive layer (e-layer) 220 may be formed on top of the p-layer 218. The emissive layer 220 may be formed from materials such as tris-(8-hydroxyquinoline)aluminum (Alq₃), or Tris[2-(p-tolyl)pyridinium-1-yl]iridium(III) (Ir(mppy)₃). The e-layer 220 may be formed to have a thickness of approximately 10-50 nm. In one example, the thickness may be approximately 30-50 nm.

The e-layer 220 may be the layer that emits light. The e-layer 220 may be formed to emit light of any desired color. For example, the e-layer 220 may be formed to emit light as a red color, a green color, or a blue color.

An n-layer 222 may be formed on top of the e-layer 220. If the layer 216 is an n-layer, then the layer 216 may be formed during the same time that the n-layer 222 is formed. The n-layer 222 and the layer 216 for an n-type TFT may be formed from a semiconductor material (e.g., Alq₃ or oligo-thiophene) and doped with n-type dopants. In one example, the n-type dopants may include phosphorus, arsenic, antimony, bismuth, lithium, or any other n-type dopants. The n-layer 222 and the layer 216 for an n-type TFT may be formed to have a thickness of approximately 10-50 nm. In one example, the thickness may be approximately 30-50 nm.

A first drain 224 and a first source 226 may be formed on the layer 216. A second source 228 and 232 and a second drain 230 may be formed on the n-layer 222. The first drain 224, the first source 226, the second source 228 and 232, and the second drain 230 may be formed at the same time during manufacturing.

In one example, the first source 226 and the second source 228 and 232 may be formed from a metal, a metallic compound, or a ceramic (e.g., including ceramic powders and build materials). Examples of metals or metallic compounds may include Mo, Al, Cu, Ti, Ag, or Au. Examples of ceramics may include transition metal oxides such as indium tin oxide (ITO), indium zinc oxide (IZO), and the like. The first source 226 and the second source 228 and 232 may be formed to have a thickness of approximately 50-500 nm. In one example, the thickness may be approximately 100 nm-300 nanometers.

In one example, the first drain 224 and the second drain 230 may be formed from a metal, a metallic compound, or a ceramic (e.g., including ceramic powders and build materials). Examples of metals or metallic compounds may include Mo, Al, Cu, Ti, Ag, or Au. Examples of ceramics may include transition metal oxides such as indium tin oxide (ITO) or indium zinc oxide (IZO). The first drain 224 and the second drain 230 may be formed to have a thickness of approximately 50-500 nm. In one example, the thickness may be approximately 60 nm-300 nanometers. In another example, the thickness may be approximately 90 nm-150 nm.

In one example, the first gate 208, the first dielectric 212, the layer 216, the first drain 224, and the first source 226 may form the TFT 204. The second gate 210, the second dielectric 214, the p-layer 218, the e-layer 220, the n-layer 222, the second source 228 and 232, and the drain 230 may form the OLET 206. As noted above, the TFT 204 and the OLET 206 may be formed on a common substrate 202. Said another way, the TFT 204 and the OLET 206 are formed side-by-side on a common substrate 202, rather than stacked on top of one another.

In addition, the design of the OLET device 104 allows the source 228 and 232 to drive current through the p-layer 218 towards the e-layer 220. In addition, the current may be applied to the drain 230 such that the drain 230 drives the current through the n-layer 222 towards the e-layer 220. The holes injected in the p-layer 218 and the electrons injected into the n-layer 222 may meet and recombine in the e-layer 220 to cause the e-layer 220 to emit light.

Moreover, the OLET device 104 allows either a p-type or n-type TFT to be formed on the substrate 202 without changing the number of layers that are formed in the OLET device 104. For example, for the p-type TFT, the layer 216 may be formed as a p-layer at the same time the p-layer 218 is formed. For the n-type TFT, the layer 216 may be formed as an n-layer at the same time the n-layer 222 is formed.

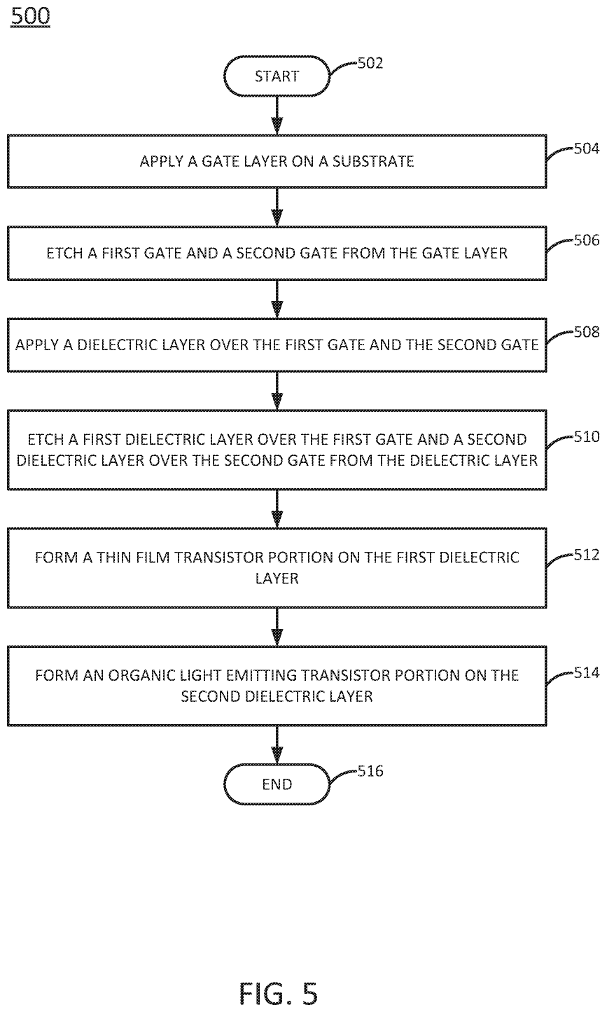

FIGS. 4A-4H illustrate block diagrams of a process flow for fabricating the OLET device 104 with the shared substrate 202. FIG. 5 illustrates a flow chart of an example method 500 for fabricating the OLET device 104 with the shared substrate 202. The method 500 may be described with reference to the FIGS. 4A-4H that illustrate how each layer may be formed for the OLET device 104.

In an example, the method 500 may be performed by various automated tools within a fabrication facility or manufacturing facility under the control of a processor or server that coordinates operation of the automated tools. The OLET device 104 may be formed via processes such as inkjet printing or vapor deposition under vacuum and non-vacuum conditions.

At block 502, the method 500 begins. At block 504, the method 500 applies a gate layer on a substrate. For example, a gate layer 209 may be deposited onto a substrate 202 via a coating process, as shown in FIG. 4A. As noted above, the gate layer 209 may be Mo, Al, Cu, Ti, Ag, Au, ITO, or IZO. The gate layer 209 may be deposited to have a thickness of approximately 50-500 nm. In one example, the thickness may be approximately 100-300 nm.

At block 506, the method 500 etches a first gate and a second gate from the gate layer. For example, a lithography process (e.g., fine metal masking or shadow masking) may be applied to the gate layer 209 to mask and pattern the gate layer 209. An etching process may be applied to the gate layer 209 to etch the gate layer 209 to form the first gate 208 and the second gate 210, as shown in FIG. 4B. As noted above, the first gate 208 may be part of the TFT 204 that is to be formed and the second gate 210 may be part of the OLET 206 that is to be formed. Both the first gate 208 and the second gate 210 may share the substrate 202.

In addition, the first gate 208 and the second gate 210 may be formed from the same gate layer 209 that was deposited onto the substrate 202. Thus, the number of layers, and thereby the processing time, can be reduced by forming the first gate 208 and the second gate 210 from the same gate layer 209 rather than separately depositing gate layers to form the gate for the TFT and the OLET.

At block 508, the method 500 applies a dielectric layer over the first gate and the second gate. For example, a dielectric layer 211 may be deposited onto the first gate 208 and the second gate 210 via a coating process, as shown in FIG. 4C. As noted above, the dielectric layer 211 may include silicon dioxide, silicon nitride, or an insulative polymer. The dielectric layer 211 may be deposited to have a thickness of approximately 100-1000 nm. In one example, the thickness may be approximately 200-500 nm.

At block 510, the method 500 etches a first dielectric layer over the first gate and a second dielectric layer over the second gate from the dielectric layer. A lithography process (e.g., fine metal masking or shadow masking) may be applied to the dielectric layer 211 to mask and pattern the dielectric layer 211. An etching process may be applied to the dielectric layer 211 to etch the dielectric layer 211 to form the first dielectric 212 and the second dielectric 214, as shown in FIG. 4D. As noted above, the first dielectric 212 may be part of the TFT 204 that is to be formed and the second dielectric 214 may be part of the OLET 206 that is to be formed.

In addition, the first dielectric 212 and the second dielectric 214 may be formed from the same dielectric layer 211 that was deposited onto the first gate 208 and the second gate 210. Thus, the number of layers, and thereby the processing time, can be reduced by forming the first dielectric 212 and the second dielectric 214 from the same dielectric layer 211 rather than separately depositing gate layers to form the gate for the TFT and the OLET.

At block 512, the method 500 forms a thin film transistor (TFT) portion on the first dielectric layer. At block 514, the method 500 forms an organic light emitting transistor (OLET) portion on the second dielectric layer. Some of the layers for the blocks 512 and 514 may occur in parallel as shown in FIGS. 4E-4H. For example, fora p-type TFT, the layer 216 may be a p-layer that can be formed at the same time as a p-layer 218 that is formed on the dielectric 214. The p-layer 218 and the layer 216 for a p-type TFT can be formed by depositing materials, such as triphenylamine and derivatives thereof, via a coating process.

An implantation, anneal, and activation process may be used to implant p-type dopants into the p-layer 218 and the layer 216 for a p-type TFT. The p-type dopants may include boron, aluminum, gallium, indium, or any other p-type dopants. The p-layer 218 and the layer 216 fora p-type TFT may be formed to be have a thickness of approximately 10-50 nm. In one example, the thickness may be approximately 30-50 nm. If the TFT 204 is an n-type TFT, then the layer 216 may be deposited later during manufacturing with an n-layer 222 as illustrated in FIG. 4G.

After the p-layer 218 is formed, an e-layer 220 may be formed on the p-layer 218, as shown in FIG. 4F. The e-layer 220 may be formed from host-dopant system materials such as N′-bis(phenyl)benzidine (NPB) or tris(carbazol-9-yl)triphenylamine (TCTA) as the host, and Alq₃, or Ir(mppy)₃ as the dopant, via an evaporation or printing process. The concentration of the dopant may be less than 20 wt %, less than 10 wt %, or approximately 2-8 wt %. The e-layer 220 may be formed to have a thickness of approximately 10-50 nm. In one example, the thickness may be approximately 30-50 nm.

FIG. 4G illustrates the formation of the n-layer 222. As noted above, if the TFT 204 is an n-type TFT, then the layer 216 may be formed at the same time the n-layer 222 is formed, rather than with the p-layer 218 as illustrated in FIG. 4E. The n-layer 222 and the layer 216 for the n-type TFT can be formed by depositing materials, such as Alq₃, oligo-thiophene, or azole-based materials (e.g., (3-(biphenyl-4-yl)-5-(4-tert-butylphenyl)-4-phenyl-4HG-1,2,4-triazole (TAZ) or 10-[4-(4,6-diphenyl-1,3,5-triazin-2-yl)phenyl]-10H-phenoxazine (PXZ-TRZ), via an evaporation or printing process.

An implantation, anneal, and activation process may be used to implant n-type dopants into the n-layer 222 and the layer 216 for an n-type TFT. The n-type dopants may include phosphorus, arsenic, antimony, bismuth, lithium, or any other n-type dopants. The n-layer 222 and the layer 216 for an n-type TFT may be formed to be have a thickness of approximately 10-50 nm. In one example, the thickness may be approximately 30-50 nm.

FIG. 4H illustrates the formation of the first drain 224, the second drain 230, the first source 226, and the second source 228 and 232. The first drain 224, the second drain 230, the first source 226, and the second source 228 and 232 may be formed from materials such as Mo, Al, Cu, Ti, Ag, Au, ITO, IZO. The first drain 224, the second drain 230, the first source 226, and the second source 228 and 232 may be deposited via a coating process. The first drain 224, the second drain 230, the first source 226, and the second source 228 and 232 may have a thickness of approximately 50-500 nm. In one example, the thickness may be approximately 200-500 nm.

Referring back to FIG. 5, after the TFT portion and the OLET portion are formed, the method 500 ends at block 516. However, it should be noted that the method 500 may be repeated for an array of OLETs on a panel or display.

In one example, the metal mask used to deposit each layer of the OLET may be different. For example, a first metal mask may be used to deposit the p-layer, a second metal mask may be used to deposit the e-layer, and a third metal mask may be used to deposit the n-layer.

It will be appreciated that variants of the above-disclosed and other features and functions, or alternatives thereof, may be combined into many other different systems or applications. Various presently unforeseen or unanticipated alternatives, modifications, variations, or improvements therein may be subsequently made by those skilled in the art which are also intended to be encompassed by the following claims.

1. An organic light emitting transistor device, comprising:
a substrate;
at least one layer deposited onto the substrate;
a thin film transistor formed on the substrate to include a first portion of the at least one layer; and
an organic light emitting transistor formed on the substrate to include a second portion of the at least one layer.

2. The organic light emitting transistor device of claim 1, wherein the at least one layer comprises a gate layer and a dielectric layer.

3. The organic light emitting transistor device of claim 1, wherein the thin film transistor comprises a p-type thin film transistor.

4. The organic light emitting transistor device of claim 1, wherein the thin film transistor comprises an n-type thin film transistor.

5. The organic light emitting transistor device of claim 1, wherein the organic light emitting transistor comprises:
a p-layer;
an emissive layer formed on top of the p-layer; and
an n-layer formed on top of the emissive layer.

6. The organic light emitting transistor device of claim 5, wherein the organic light emitting transistor comprises:
a source to drive current through the p-layer towards the emissive layer; and
a drain formed on top of the n-layer to drive the current the current through the n-layer towards the emissive layer.

7. An organic light emitting transistor device, comprising:
a substrate;
a first gate and a second gate formed on the substrate from a single gate layer;
a first dielectric formed over the first gate and a second dielectric formed over the second gate from a single dielectric layer;
a first p-layer or a first n-layer formed on top of the first dielectric and a second p-layer formed on top of the second dielectric;
an emissive layer formed on top of the second p-layer;
a second n-layer formed on top of the emissive layer; and
a first source and a first drain formed on the first p-layer or the first p-layer and a second source and a second drain formed on the second n-layer.

8. The organic light emitting transistor device of claim 7, wherein the first gate, the first dielectric, the first p-layer or the first n-layer, the first source, and the first drain form a thin film transistor of the organic light emitting transistor.

9. The organic light emitting transistor device of claim 8, wherein the first p-layer is formed on top of the first dielectric when the thin film transistor is a p-type thin film transistor.

10. The organic light emitting transistor device of claim 8, wherein the first p-layer is formed on top of the first dielectric when the thin film transistor is an n-type thin film transistor.

11. The organic light emitting transistor device of claim 7, wherein the substrate comprises a glass or a plastic.

12. The organic light emitting transistor device of claim 7, wherein the gate layer, the first source, the first drain, the second source, and the second drain comprise a metal, a metallic compound, or a ceramic.

13. A method, comprising:
applying a gate layer on a substrate;
etching a first gate and a second gate from the gate layer;
applying a dielectric layer over the first gate and the second gate;
etching a first dielectric layer over the first gate and a second dielectric layer over the second gate from the dielectric layer;
forming a thin film transistor on the first dielectric layer and the first gate; and
forming an organic light emitting transistor on the second dielectric layer and the second gate.

14. The method of claim 13, wherein forming the organic light emitting transistor comprises:
forming a p-layer on the second dielectric;
forming an emissive layer on the p-layer;
forming an n-layer on the emissive layer; and
forming an organic light emitting transistor source and an organic light emitting transistor drain on the n-layer.

15. The method of claim 14, wherein forming the thin film transistor comprises:
forming a p-layer on the first dielectric with the p-layer of the organic light emitting transistor when the thin film transistor is a p-type device or forming an n-layer on the first dielectric with the n-layer of the organic light emitting transistor when the thin film transistor is an n-type device; and
forming a thin film transistor source and a thin film transistor drain on the p-layer or the n-layer of the thin film transistor with the organic light emitting transistor source and the organic light emitting transistor drain.
